(19) United States
(12) Patent Application Publication
(10) Pub. No.: US 2009/0194150 A1
(43) Pub. Date: Aug. 6, 2009

(54) SOLAR CELL AND METHOD FOR FABRICATING THE SAME

(76) Inventor: Satoshi Aoki, Tochigi (JP)

Correspondence Address: ARENT FOX LLP, 1050 CONNECTICUT AVENUE, N.W., SUITE 400, WASHINGTON, DC, 20036, US

(21) Appl. No.: 12/162,727

(22) PCT Filed: Jan. 26, 2007
(86) PCT No.: PCT/JP2007/051302

§ 371 Date: Aug. 27, 2008

(30) Foreign Application Priority Data
Jan. 30, 2006 (JP) 2006-019969

(51) Int. Cl. H01L 31/0224; H01L 31/18

(52) U.S. Cl. 136/252; 438/69; 257/E31.124

(57) ABSTRACT

A cell 10 (unit cell) constituting a unit is formed from a lower electrode layer 2 (Mo electrode layer) formed on a texture substrate 1 formed with recesses and projections at a surface thereof, a light absorbing layer 3 (CIGS light absorbing layer) including copper, indium, gallium, selenium, a buffer layer thin film 4 of a high resistance formed by InS, ZnS, CdS or the like and an upper electrode layer 5 (TCO) formed by ZnOAl or the like on the light absorbing layer 3, further, a contact electrode portion 6 for connecting the upper electrode layer 5 and the lower electrode layer 2 is formed with an object of connecting a plurality of the unit cells 10 in series. As described later, a Cu/In rate of the contact electrode portion 6 is larger than a Cu/In rate of the light absorbing layer 3, in other words, In is constituted to be small, showing a characteristic of P+ (plus) type or a conductor relative to the light absorbing layer 3 constituting a p type semiconductor.

### TECHNICAL FIELD

The present invention relates to a solar cell of a chalcopyrite type constituting a solar cell of a compound group and its fabricating method, particularly relates to a solar cell characterized in that a substrate having recesses and projections on a surface thereof is used and a contact electrode portion for connecting unit cells of the solar cell in series and its fabricating method.

### RELATED ART

A solar cell for receiving light and converting light into an electric energy is classified to a bulk group and a thin film group by a thickness of a semiconductor. Among them, the thin film group is a solar cell having a thickness of a semiconductor layer of several tens μm through several μm or smaller and is classified into a Si thin film group and a compound thin film group. Further, there are kinds of a II-VI group compound group, a chalcopyrite group and the like in the compound thin film group and a number thereof has been reduced into a product. Among them, a chalcopyrite type solar cell belonging to the chalcopyrite group is referred to as another name of a CIGS (Cu(InGa)Se) group thin film solar cell or a CIGS solar cell or I-III-VI group in view of a substance used.

The chalcopyrite solar cell is a solar cell of forming a light absorbing layer by a chalcopyrite compound and is characterized in a high efficiency, without optical deterioration (aging change), excellent in radiation resistance, having a wide light absorbing wavelength region, having a high light absorption coefficient and the like and currently, a research for mass production has been carried out.

FIG. 1 shows a sectional structure of a general chalcopyrite type solar cell. As shown by FIG. 1, a chalcopyrite type solar cell is formed by a lower electrode layer (Mo electrode layer) formed on a substrate of glass or the like, a light absorbing layer (CIGS light absorbing layer) including copper, indium, gallium, selenium, a buffer layer thin film having a high resistance formed by InS, ZnS, CdS or the like on the light absorbing layer thin film, and an upper electrode thin film (TCO) formed by ZnOAl or the like. Further, when a soda-lime glass is used for the substrate, there is also a case of providing an alkali control layer whose major component is SiO₂ or the like with an object of controlling an amount of invasion of an alkali metal component from inside of the substrate to the light absorbing layer.

When light of solar ray or the like is irradiated to the chalcopyrite type solar cell, a pair of electron (−) and hole (+) is generated at inside of the light absorbing layer, with regard to electron (−) and hole (+); at a junction face of a p type semiconductor and an n type semiconductor, electron (−) is gathered to the n type semiconductor and hole (+) is gathered to the p type semiconductor, as a result, an electromotive force is generated between the n type semiconductor and the p type semiconductor. A current can be outputted to outside by connecting a conductor to the electrodes under the state.

FIG. 2 shows steps of fabricating a chalcopyrite type solar cell. First, an Mo (molybdenum) electrode constituting a lower electrode is formed on a glass substrate of soda-lime glass or the like by sputtering. Next, as shown by FIG. 2 (a), the Mo electrode is divided by removing the Mo electrode by irradiating a laser or the like (first scribe).

After the first scribe, a machined chip is cleaned by water or the like, copper (Cu), indium (In) and gallium (Ga) are adhered thereto by sputtering or the like to form a precursor. The precursor is put into a furnace and annealed in an atmosphere of H₂Se gas to thereby form a thin film of a light absorbing layer of a chalcopyrite type. The annealing step is referred to normally as a gas phase selenidation or simply selenidation.

Next, an n type buffer layer of CdS, ZnO or InS or the like is laminated on the light absorbing layer. The buffer layer is formed by a method of sputtering or CBD (chemical bath deposition) or the like. Next, as shown by FIG. 2 (b), the buffer layer and the precursor are divided by removing the buffer layer and the precursor by laser irradiation, a metal needle or the like (second scribe). FIG. 3 shows a behavior of scribe by a metal needle.

Thereafter, as shown by FIG. 2 (c), a transparent electrode (TCO: Transparent Conducting Oxides) film is formed as an upper electrode by sputtering or the like. Finally, as shown by FIG. 2 (d), a CIGS group thin film solar cell is finished by dividing the upper electrode (TCO), the buffer layer and the precursor by laser irradiation, a metal needle or the like (third scribe: element isolation).

The solar cell provided here is referred to as cell constituted by connecting respective unit cells monolithically and in series, when actually used, a single or a plurality of cells are packaged and worked as a module (panel). The cell is constituted by connecting the plurality of cells in series by the respective scribe steps, and in a thin film type solar cell, a voltage of the cell can arbitrarily be designed to change by changing a number of series stages (number of unit cells)

As prior arts with regard to the second scribe, Patent Reference 1 and Patent Reference 2 are pointed out. As shown by FIG. 3, Patent Reference 1 discloses a technology of scribing a light absorbing layer and a buffer layer by moving a metal needle (needle) a front end of which is constituted by a taper shape while pressing the metal needle by a predetermined pressure.

Further, Patent Reference 2 discloses a technology of removing and dividing a light absorbing layer by irradiating a laser (Nd: YAG laser) constituted by exciting Nd: YAG crystal by a continuous discharging lamp of an arc lamp or the like to the light absorbing layer.

As has been described above, according to the chalcopyrite type solar cell of the background art, a glass substrate having a flat face has been used for a substrate material thereof.

As disclosed in Patent Reference 3, in a solar cell of a silicon thin film group, there has been developed a technology of promoting a conversion efficiency by a light confining effect by forming a solar cell by using a glass substrate formed with recesses and projections on a surface thereof (texture substrate), forming an electrode on the glass substrate and successively laminating a silicon semiconductor.

### Patent Reference 1: JP-A-2004-115356

### Patent Reference 2: JP-A-11-312815

### Patent Reference 3: JP-A-2-164077

### DISCLOSURE OF THE INVENTION

### Problems to be solved by the Invention

The texture substrate of the background art disclosed in Patent Reference 3 cannot be applied to a chalcopyrite type solar cell constituting a solar cell of a compound group. The reason is that when recesses and projections are present at the substrate, the second scribe cannot be carried out, and a monolithic series stage number connecting structure cannot be adopted.

For example, in mechanical scribe of mechanically machining in the technology of carrying out the second scribe, a series resistance of the solar cell is increased.

Explaining further in details based on a photograph taken from an upper face of a substrate after carrying out mechanical scribe of FIG. 4, FIG. 4 (a) is a photograph when a glass substrate a surface of which is smooth is used, and (b) is a photograph when a texture substrate a surface of which is provided with recesses and projections is used.

As shown by FIG. 4 (b), when the second scribe is carried out in a case of using the texture substrate, a residue of the scribe is clearly brought about. This is brought about since a diameter of a metal needle (needle) used in mechanical scribe is wider than intervals of recesses and projections of the texture substrate. That is, whereas a period of recesses and projections (a distance in transverse direction from a maximum height to a minimum height) used in an experiment of FIG. 4 is 5.9 μm, a diameter of a front end portion of the needle is 35 μm and the front end portion of the needle is provided with a diameter about 6 times as much as the period.

The light absorbing layer which is not removed by the needle in this way remains between the transparent electrode and the lower electrode after laminating the transparent electrode (TCO) The light absorbing layer is provided with a resistivity of about 10⁴ Ω·cm, on the other hand, the resistivity is sufficiently higher than a resistivity of 5.4×10⁻⁶ Ω·cm of molybdenum constituting the lower electrode, when a portion of the light absorbing layer is present as a residue, a resistance value is increased, and the conversion efficiency (power generation efficiency) of light energy is reduced.

Further, in scribe using laser light as shown by Patent Reference 2, it is difficult to adjust a strength of laser light to follow recesses and projections of a glass substrate.

That is, owing to recesses and projections provided to a texture substrate, a thickness of a light absorbing layer or an angle of incidence of laser are not uniform and it is extremely difficult to adjust laser light to a strength of removing only the light absorbing layer. That is, when the irradiated laser light is strong, after removing the light absorbing layer, the laser light is further irradiated, as a result, the lower electrode (Mo electrode) is destructed. Further, when the laser light is weak, the light absorbing layer remains without being removed to constitute a layer having a high resistance as described above, and therefore, there poses a problem that a contact resistance between the upper transparent electrode (TCO) and the lower Mo electrode is extremely deteriorated.

In this way, there is a significant disadvantage in applying second scribe to the texture substrate of the background art, and it is difficult to form the monolithic series connecting structure to a chalcopyrite type solar cell.

### Means for Solving the Problems

In order to resolve the above-described problem, there is provided a solar cell including:

a substrate having recesses and projections at a main face thereof;

a plurality of lower electrodes formed on a side of the main face of the substrate and constituted by dividing a conductive layer;

a light absorbing layer of a chalcopyrite type formed on the plurality of lower electrodes and divided into a plurality thereof;

a plurality of upper electrodes constituting a transparent conductive layer formed on the light absorbing layer; and

a contact electrode portion constituted by denaturing a portion of the light absorbing layer to connect unit cells constituted by the lower electrode layers, the light absorbing layers and the upper electrodes in series, and having a conductivity higher than a conductivity of the light absorbing layer.

A basic constitution of the solar cell according to the invention is constituted by laminating the lower electrode, the light absorbing layer and the upper electrode on the substrate as described above, the respective layers are indispensable constituent elements constituting the solar cell according to the invention and also the basic constitution interposed with a buffer layer, an alkali passivation film, a reflection preventing film and the like as necessary among the respective layers is included in the solar cell of the invention.

The contact electrode portion functions as an electrode by being denatured from a p type semiconductor by making a Cu/In rate thereof higher than a Cu/In rate of the light absorbing layer by being denatured. Further, when the lower electrode comprises molybdenum (Mo), the contact electrode portion is denatured to an alloy including molybdenum.

Further, there is provided a method of fabricating a solar cell including:

a lower electrode forming step of forming a lower electrode layer on a side of a main face of a substrate having recesses and projections at a main face thereof;

a first scribe step of dividing the lower electrode layer into a plurality of lower electrodes;

a light absorbing layer forming step of forming a light absorbing layer of a chalcopyrite type on the plurality of lower electrodes;

a contact electrode portion forming step of irradiating laser light to a portion of the light absorbing layer to be denatured such that a conductivity of the portion becomes high;

a transparent conductive layer forming step of forming a transparent conductive layer constituting an upper electrode on the light absorbing layer and the contact electrode portion; and

a second scribe step of dividing the transparent conductive layer into a plurality of upper electrodes.

Further, if a step of forming a buffer layer is provided after the light absorbing layer forming step, the laser light is irradiated from on the buffer layer.

### ADVANTAGE OF THE INVENTION

According to the invention, the contact electrode portion is constituted by denaturing the light absorbing layer per se without scribing a portion of the light absorbing layer, and therefore, a resistance is not increased by thinning a portion of connecting the unit cells as in the background art. Further, even when the texture substrate having recesses and projections at the surface is used as the substrate, the second scribe is not carried out, and therefore, a disadvantage that the lower electrode (Mo electrode) is destructed and a portion of the light absorbing layer remains without being removed is not brought about.

Further, by using the texture substrate as the substrate, the electrode layer formed on the substrate is made to be difficult to be exfoliated, further, a light receiving area is increased, and therefore, a photoelectric conversion efficiency is promoted.

### BRIEF DESCRIPTION OF THE DRAWINGS

FIG. 1 is a sectional view showing a structure of a chalcopyrite type solar cell of a background art.

FIG. 2 illustrates views showing a series of fabricating steps of the chalcopyrite type solar cell of the background art.

FIG. 3 is a view showing a behavior of scribe by a metal needle.

FIG. 4 illustrates photographs taken from an upper face of a substrate after carrying out mechanical scribe, (a) is a photograph when a glass substrate a surface of which is smooth is used, and (b) is a photograph when a texture substrate a surface of which is provided with recesses and projections is used.

FIG. 5 is a sectional view of an essential portion of a chalcopyrite type solar cell according to the invention.

FIG. 6 is a view showing a method of fabricating a chalcopyrite type solar cell of the invention.

FIG. 7 is an SEM photograph taking a light absorbing layer and a surface of a contact electrode after irradiating a laser.

FIG. 8

(a) is a graph showing a content analyzing result of a light absorbing layer in which a laser contact forming step is not carried out, and (b) is a graph showing a content analyzing result of a laser contact portion in which a laser contact forming step is carried out.

[FIG. 9]

(a) is a graph showing a difference of a carrier concentration of a light absorbing layer by a Cu/In rate, and (b) is a graph showing a change in a resistivity by a Cu/In rate.

FIG. 10 is an SEM photograph of a surface of a solar cell formed with a contact electrode portion by a laser contact forming step of the invention.

FIG. 11 is an SEM photograph of sections of a contact electrode portion and a light absorbing layer.

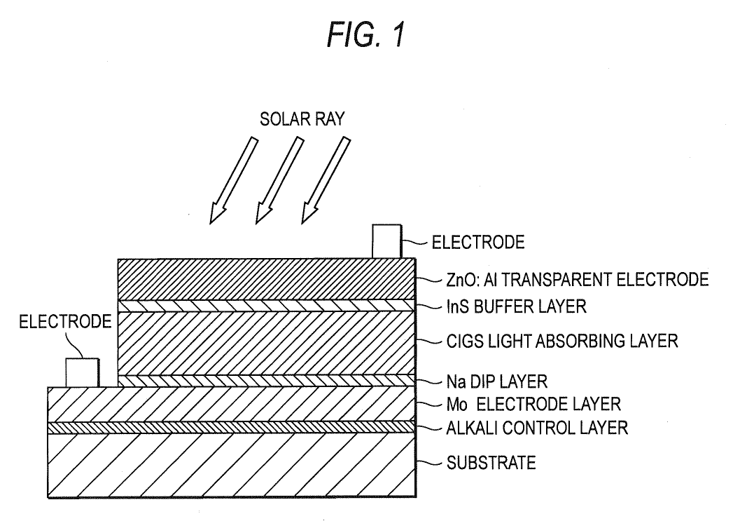

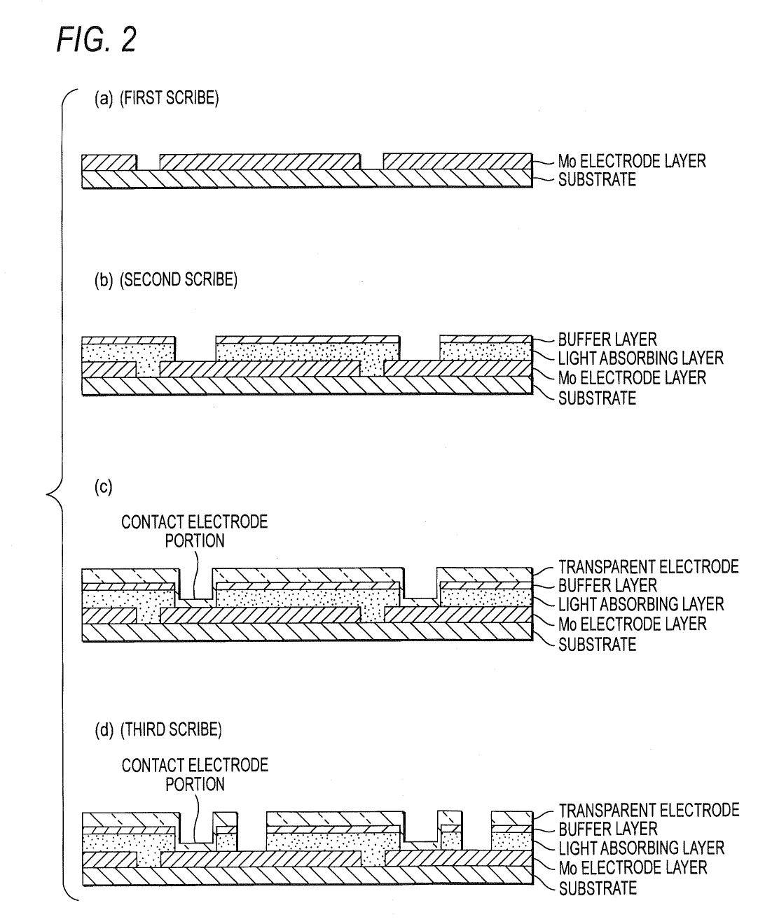

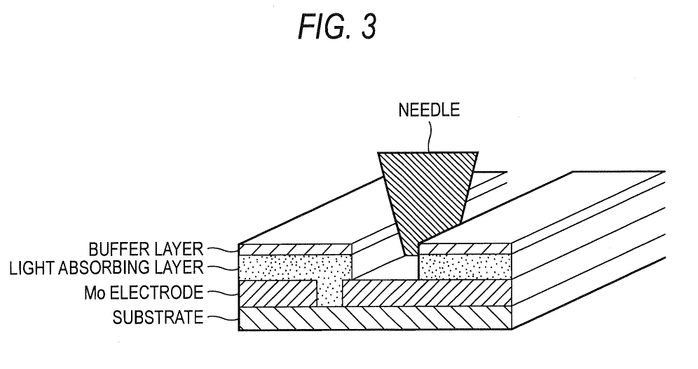

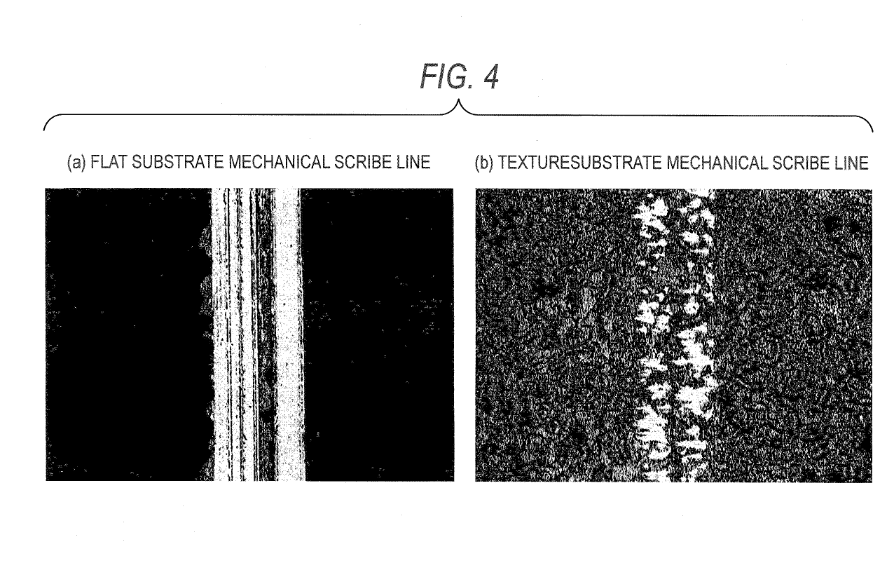

### DESCRIPTION OF REFERENCE NUMERALS AND SIGNS

1 . . . substrate
2 . . . lower electrode layer
3 . . . light absorbing layer
4 . . . buffer layer thin film
5 . . . upper electrode layer
6 . . . contact electrode portion

### BEST MODE FOR CARRYING OUT THE INVENTION

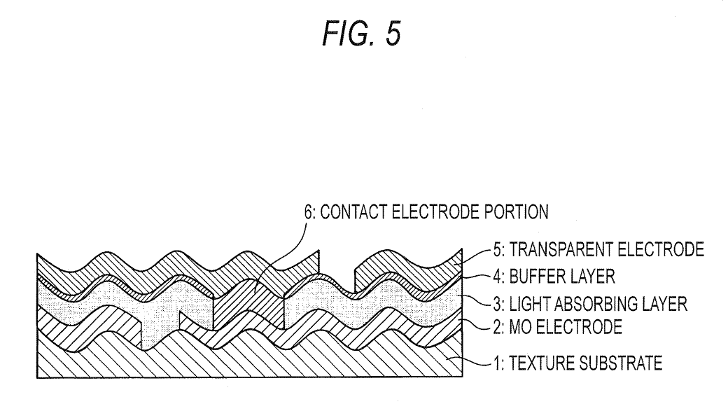

FIG. 5 shows a solar cell of a chalcopyrite type according to the invention. Here, FIG. 5 is a sectional view of an essential portion of the solar cell (cell)

A chalcopyrite type solar cell according to the invention is formed with a cell (unit cell) constituting a unit from a lower electrode layer 2 (Mo electrode layer) formed on a substrate 1 (texture substrate) of glass or the like provided with recesses and projections at a surface thereof, a light absorbing layer 3 (CIGS light absorbing layer) including copper, indium, gallium, selenium, a buffer layer thin film 4 of a high resistance formed by InS, ZnS, CdS or the like on the light absorbing layer 3, and an upper electrode layer 5 (transparent electrode layer: TCO) formed by ZnOAl or the like, further, with an object of connecting a plurality of the unit cells in series, a contact electrode portion 6 connecting the upper electrode layer 5 and the lower electrode layer 2 is formed.

According to the contact electrode portion 6, as described later, a Cu/In rate is larger than a Cu/In rate of the light absorbing layer 3, in other words, the contact electrode portion 6 is constituted by a small amount of In, showing a characteristic of p+ (plus) type or a conductor relative to the light absorbing layer 3 constituting a p type semiconductor.

Further, although according to the embodiment, glass is shown as a material of the texture substrate, the texture may be provided with a resistance against heat of about 650° C., and a resistance against a gas phase selenidation step, and therefore, the material is not limited to glass but may be, for example, a substrate including mica or polyimide, ceramic, stainless steel or carbon or the like coated with an insulating coating.

A texture substrate is provided with recesses and projections at a surface thereof by subjecting a substrate (glass) constituting a material to a physical machining step of sandblast or the like or a chemical treating step of hydrofluoric acid or the like. According to the embodiment, there is used a texture substrate having sizes of recesses and projections of an average of a high and low difference of 2.1 μm, and an average of a distance in a transverse direction from a maximum height to a minimum height of 5.9 μm.

By using the texture substrate, an adherence of the substrate and molybdenum constituting the lower electrode is promoted, further, a contact area of the lower electrode and the light absorbing layer is widened, and therefore, an electric resistance is reduced. Further, an optical path length can be prolonged when light is incident on the buffer layer to reach a pn junction portion, and therefore, an effect can be achieved also with regard to alight confining effect. Further, the light confining effect increases a light energy staying at the pn junction portion for a long period of time by prolonging the optical length (that is, light is confined), as a result, photoelectric conversion is considerably promoted.

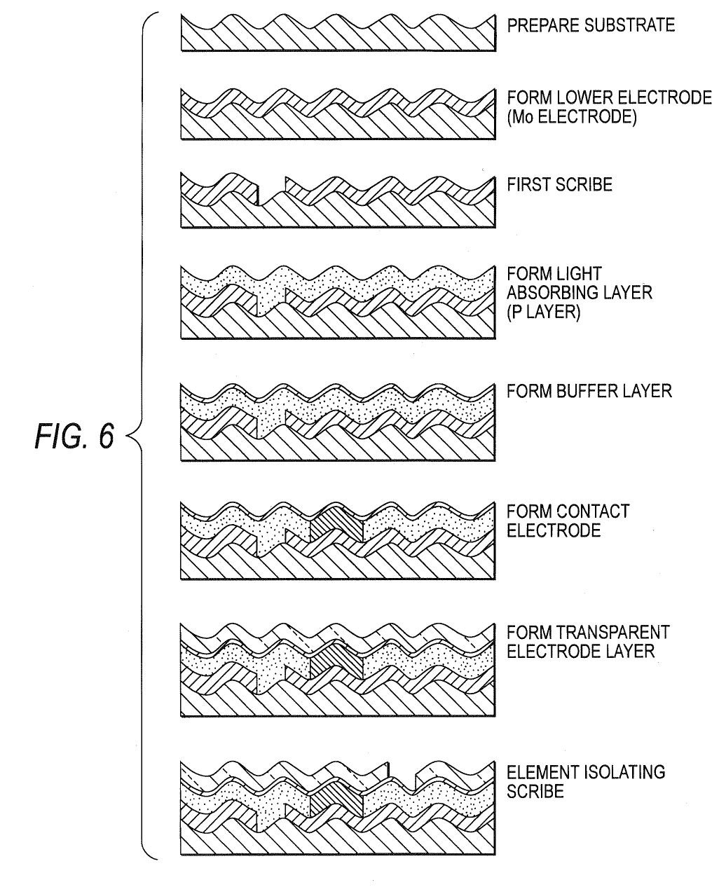

Next, FIG. 6 shows a method of fabricating a chalcopyrite type solar cell of the invention. First, an Mo (molybdenum) electrode constituting a lower electrode is formed at a texture substrate by sputtering or the like. Titanium or tungsten can be used for the lower electrode other than molybdenum.

Next, the lower electrode (molybdenum Mo electrode) is divided by laser irradiation or the like. (first scribe)

As a laser, an excimer laser having a wavelength of 256 nm or a third harmonic of a YAG laser having a wavelength of 355 nm is preferable. Further, it is preferable to ensure about 80 through 100 nm as a work width of a laser, thereby, insulation between Mo electrodes contiguous to each other can be ensured.

After the first scribe, copper (Cu), indium (In), gallium (Ga) are adhered by sputtering, vapor deposition or the like to form a layer referred to as precursor.

A light absorbing layer thin film is provided by putting the precursor into a furnace and annealing the precursor at a temperature of about 400° C. through 600° C. in an atmosphere of H₂Se gas. The annealing step is referred to normally as gas phase selenidation or, simply, selenidation.

Further, a number of technologies have been developed in a step of forming the light absorbing layer, such as a method of carrying out anneal after forming Cu, In, Ga, Se by vapor deposition. Although according to the embodiment, an explanation has been given by using gas phase selenidation, according to the invention, the step of forming the light absorbing layer is not limited.

Next, a buffer layer constituting a semiconductor of an n type of CdS, ZnO, InS or the like is laminated on the light absorbing layer. The buffer layer is formed by a dry process of sputtering or the like or a wet process of CBD (chemical bath deposition) or the like as a general process.

Further, the buffer layer can also be omitted by improving a transparent electrode described later.

Next, a contact electrode portion is formed by denaturing the light absorbing layer by irradiating a laser. Further, although the laser is irradiated also to the buffer layer, the buffer layer per se is formed to be extremely thinner than the light absorbing layer and an influence by presence or absence of the buffer layer is not observed even by an experiment of the inventors.

Thereafter, a transparent electrode (TCO) of ZnOAl or the like constituting an upper electrode is formed by sputtering or the like on the buffer layer and the contact electrode. Finally, TCO, the buffer layer and the precursor are removed and divided by laser irradiation, a metal needle or the like (element isolating scribe).

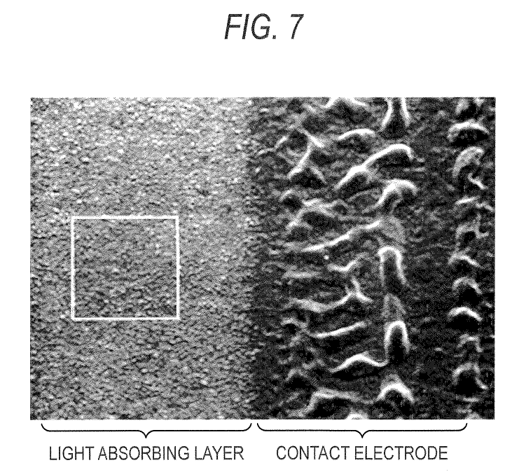

FIG. 7 shows an SEM photograph of taking the light absorbing layer and a surface of the contact electrode after irradiating the laser. As shown by FIG. 7, it is known that relative to the light absorbing layer which has grown into a granular shape, the contact electrode is recrystallized by melting a surface thereof by an energy of a laser.

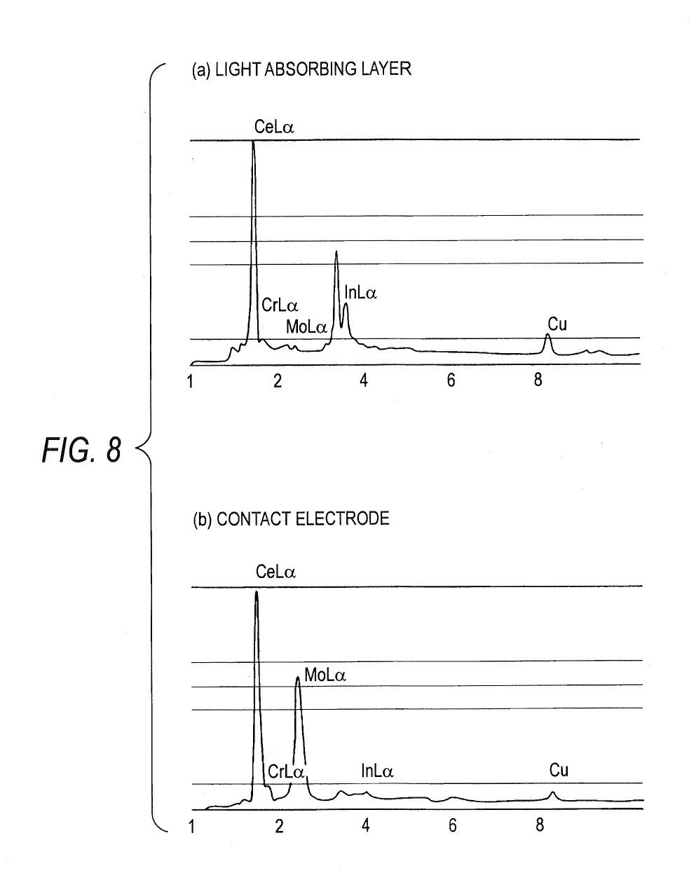

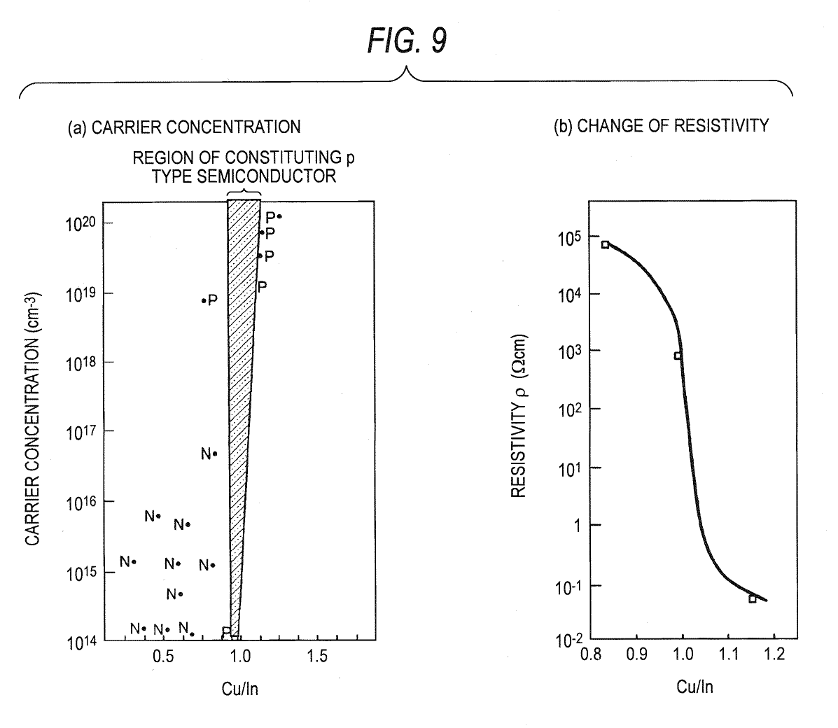

In order to analyze further in details, the contact electrode formed by the invention is verified by comparing the contact electrode with the light absorbing layer before irradiating the laser in reference to FIG. 8.

FIG. 8 (a) shows a content analyzing result of a light absorbing layer in which a laser contact forming step is not carried out, (b) shows a content analyzing result of a laser contact portion in which the laser contact forming step is carried out. Further, EPMA (Electron Probe Micro-Analysis) is used for the analysis. EPMA detects constituent elements by analyzing a spectrum of a characteristic X-ray generated by exciting an electron beam by irradiating an accelerated electron to a substance and analyzing rates (concentration) of the respective constituent elements.

It is known from FIG. 8, indium (In) is remarkably reduced in the contact electrode relative to the light absorbing layer. When a width of reduction is accurately counted by an EPMA apparatus, the width is 1/3.61. Similarly, when attention is paid to copper (Cu) and a width of reduction thereof is counted, the width is 1/2.37. In this way, it is known that by irradiating the laser, In is remarkably reduced, In is reduced more than Cu in the rate.

As other characteristic, molybdenum (Mo) which has been hardly detected in the light absorbing layer is detected. Reason of the change will be investigated. According to a simulation by the inventors, for example, when laser light having a wavelength of 355 nm is irradiated by 0.1 J/cm², a surface temperature of the light absorbing layer is elevated to about 6,000° C. Although a temperature is naturally lowered on an inner (lower) side of the light absorbing layer, the light absorbing layer used in the embodiment is of 1 μm, it can be said that also the inner portion of the light absorbing layer becomes a considerably high temperature. Here, a melting point of indium is 156° C., a boiling point thereof is 2,000° C., further, a melting point of copper is 1,084° C. and a boiling point thereof is 2,595° C. Therefore, it is predicted that in comparison with copper, indium reaches the boiling point at a deeper portion of the light absorbing layer. Further, it is predicted that a melting point of molybdenum is 2,610° C., and therefore, a some degree of molybdenum present at the lower electrode is melted and incorporated to a side of the light absorbing layer.

First, consider a change in a characteristic by a change in a rate of copper and indium.

FIG. 9 shows the change in the characteristic by the Cu/In rate. FIG. 9 (a) shows a difference in a carrier concentration of a light absorbing layer by the Cu/In rate and FIG. 9 (b) shows a change in a resistivity by the Cu/In rate.

As shown by FIG. 9 (a), for being used as the light absorbing layer, it is necessary to control the Cu/In rate to about 0.95 through 0.98. As shown by FIG. 8, in the contact electrode processed by the contact electrode portion forming step by being irradiated with the laser, the Cu/In rate is changed to a value larger than 1 from measured amounts of copper and indium. Therefore, it seems that the contact electrode is changed to p+ (plus) type or a metal. Here, when attention is paid to FIG. 9 (b), the resistivity is rapidly lowered as the Cu/In rate becomes a value larger than 1. Specifically, whereas when the Cu/In rate is 0.95 through 0.98, the resistivity is about 10⁴ Ω·cm, when the Cu/In rate is changed to 1.1, the resistivity is rapidly reduced to about 0.1 Ωcm

Next, molybdenum melted and incorporated to the side of the light absorbing layer will be investigated.

Molybdenum is a metal element belonging to 6 group of a periodic table, showing characteristic of a specific resistance of 5.4×10⁻⁶ Ωcm. By melting and recrystallizing the light absorbing layer in the form of incorporating molybdenum, the resistivity is reduced.

It seems from the above-described two reasons that the contact electrode is denatured into p+ (plus) type or a metal and a resistance thereof becomes lower than that of the light absorbing layer.

Next, an explanation will be given of lamination of the transparent electrode layer to the contact electrode portion.

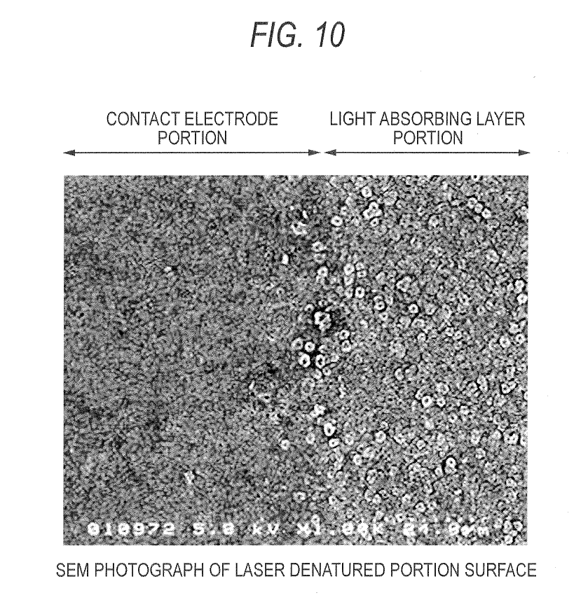

FIG. 10 shows an SEM photograph of taking a surface of a solar cell after laminating TCO. In the scribe of the background art, the light absorbing layer remains on the texture substrate, and therefore, it is difficult to eliminate the light absorbing layer without damaging the Mo electrode. However, according to the invention, as shown by FIG. 10, the monolithic series connecting structure is formed by the contact electrode layer constituted by denaturing the light absorbing layer. Further, a stepped difference in correspondence with a film thickness of the light absorbing layer is not present, and therefore, a defect is not brought about in the transparent electrode.

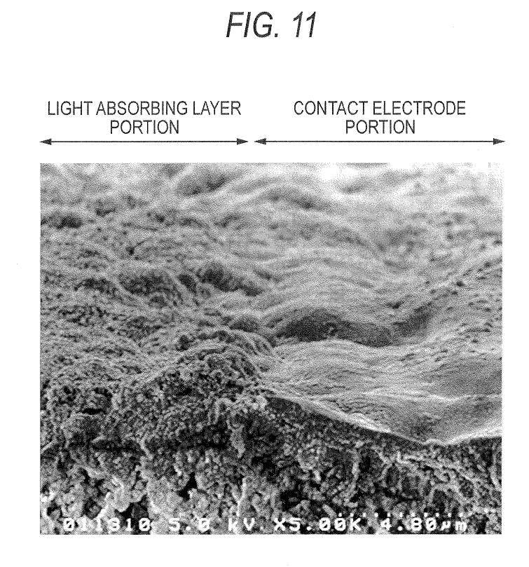

In order to make clear that a thickness of the contact electrode layer is not changed considerably in comparison with a thickness of the light absorbing layer, FIG. 11 shows an SEM photograph of sections of the contact electrode portion and the light absorbing layer. The contact electrode portion shown in FIG. 11 is irradiated with 5 times of a laser having a frequency of 20 KHz, an output of 467 mW and a pulse width of 35 ns. The number of times is constituted by 5 times in order to observe a reduction in a film thickness of the contact electrode portion by irradiating the laser.

As shown by FIG. 11, it is known that even when the laser is irradiated by 5 times, the film thickness of the contact electrode portion considerably remains.

### INDUSTRIAL APPLICABILITY

In this way, by adopting the contact electrode portion forming step of irradiating the laser instead of the second scribe in the case of a material of a substrate having recesses and projections at the surface, the contact electrode portion constituted by denaturing the light absorbing layer can be provided. Thereby, an inner resistance of series connection can be alleviated, and the solar cell of the chalcopyrite type having the high photoelectric conversion efficiency can be provided.

Although the invention has been explained in details and in reference to the specific embodiments, it is apparent for the skilled person that the invention can variously be changed or modified without deviating from the spirit and the range of the invention.

The application is based on Japanese Patent Application (Japanese patent Application No. 2006-019969) filed on Jan. 30, 2006, and a content thereof is incorporated herein by reference.

1. A solar cell comprising:
a substrate having recesses and projections at a main face thereof;
a plurality of lower electrodes formed on a side of the main face of the substrate and constituted by dividing a conductive layer;
a light absorbing layer of a chalcopyrite type formed on the plurality of lower electrodes and divided into a plurality thereof;
a plurality of upper electrodes constituting a transparent conductive layer formed on the light absorbing layer; and
a contact electrode portion constituted by denaturing a portion of the light absorbing layer to connect unit cells constituted by the lower electrode layers, the light absorbing layers and the upper electrodes in series, and having a conductivity higher than a conductivity of the light absorbing layer.

2. The solar cell according to claim 1, wherein
a Cu/In rate of the contact electrode portion is higher than a Cu/In rate of the light absorbing layer.

3. The solar cell according to claim 1, wherein
the contact electrode portion is an alloy including molybdenum.

4. The solar cell according to claim 1, wherein
a buffer layer is formed between the light absorbing layer and the upper electrode.

5. A method of fabricating a solar cell comprising:
a lower electrode forming step of forming a lower electrode layer on a side of a main face of a substrate having recesses and projections at a main face thereof;
a first scribe step of dividing the lower electrode layer into a plurality of lower electrodes;
a light absorbing layer forming step of forming a light absorbing layer of a chalcopyrite type on the plurality of lower electrodes;
a contact electrode portion forming step of irradiating laser light to a portion of the light absorbing layer to be denatured such that a conductivity of the portion becomes high;
a transparent conductive layer forming step of forming a transparent conductive layer constituting an upper electrode on the light absorbing layer and the contact electrode portion; and
a second scribe step of dividing the transparent conductive layer into a plurality of upper electrodes.

6. The method of fabricating a solar cell according to claim 5, further comprising:
a step of forming a buffer layer provided after the light absorbing layer forming step, wherein
at the contact electrode portion forming step, the laser light is irradiated from on the buffer layer.
